(19) United States
(12) Patent Application Publication
(10) Pub. No.: US 2007/0084633 A1
(43) Pub. Date: Apr. 19, 2007

(54) Electromagnetic relay with noise reducing sealant

(75) Inventors: Albert Yong Lee, Greensboro, NC (US); Roger Lee Thrush, Clemmons, NC (US); Robert Daniel Irlbeck, Greensboro, NC (US)

Correspondence Address: Lisa B. Vaccarelli;Tyco Electronic Corporation, Suite 140, 4550 New Linden Hill Road, Wilmington, DE, 19808, US

(73) Assignee: Tyco Electronic Corporation

(21) Appl. No.: 11/232,327

(22) Filed: Sep. 21, 2005

(51) Int. Cl. H01L 23/02

(52) U.S. Cl. 174/564

(57) ABSTRACT

An electromagnetic relay includes a base configured to support relay components. The base has a perimeter edge. A cover is joined to the base to define an interior volume. The cover has a lower edge held proximate the perimeter edge of the base. The lower edge and the perimeter edge have a gap therebetween. A soft sealant is provided between the lower edge of the cover and the perimeter edge of the base to fill the gap. The soft sealant forms a noise attenuating seal between the cover and the base. The soft sealant forms an air tight seal between the base and the cover when the soft sealant is cured. The soft sealant includes a heat cured epoxy having a Shore A hardness of about forty five. A plurality of electrical terminals extend through the base to form a terminal gap between the terminals and the base. The soft sealant fills the terminal gap.

### BACKGROUND OF THE INVENTION

This invention relates generally to electromagnetic relays, and more specifically to a relay having noise reduction characteristics when the relay is energized and de-energized.

A typical electromagnetic relay includes a contact mounted on an armature that is held in an open position by a spring. A coil wound core attracts the armature to the core when sufficient current is passed through the coil to energize the core to overcome the spring and attract the armature to the core. An audible sound is made when the contact engages the core. An audible sound is also made when the core is de-energized and the contact is released from the core.

Relays of the type described above, as well as comparable relays, are used extensively in automotive applications to control various electrical components such as headlight switching between high and low beams, windshield wipers, audio systems, air conditioning compressors, starter motors, and the like. The sound produced by the relays when energized and de-energized may be heard inside the passenger compartment and may be objectionable.

Various approaches have been taken to reduce the energizing and de-energizing noise made by such relays. For instance, U.S. Pat. No. 6,798,322 describes a prior art apparatus to reduce acoustic noise in relays a relatively soft die cut plastic or rubber pad 44 has been positioned between the armature 40 and the spring 42. Although the specific purpose of this pad 44 is not known, it may tend to reduce the audible noise which may otherwise occur during pull-in and/or drop-out. However, inclusion of this pad 44 between the armature 40 and spring 42 can significantly complicate fabrication of this subassembly. The '322 patent itself describes an alternative approach wherein a flexible insert is mounted on the relay armature to decelerate the armature upon impact with the core. In another alternative approach, U.S. Pat. No. 4,844,401 describes a mounting assembly for securing a control relay to a vehicle chassis, wherein the mounting assembly includes sound absorbing members.

While the aforementioned solutions have met with varying degrees of success, a need still remains for a system that reduces objectionable noise from the operation of a relay that can be easily applied without unduly complicating the manufacturing process for the relay.

### BRIEF DESCRIPTION OF THE INVENTION

In one aspect, an electromagnetic is provided. The relay includes a base configured to support relay components. The base has a perimeter edge. A cover is joined to the base to define an interior volume. The cover has a lower edge held proximate the perimeter edge of the base. The lower edge and the perimeter edge have a gap therebetween. A soft sealant is provided between the lower edge of the cover and the perimeter edge of the base to fill the gap. The soft sealant forms a noise attenuating seal between the cover and the base.

Optionally, the soft sealant forms an air tight seal between the base and the cover when the soft sealant is cured. The soft sealant includes a heat cured epoxy having a Shore A hardness of about forty five. A plurality of electrical terminals extend through the base to form a terminal gap between the terminals and the base, and the soft sealant fills the terminal gap.

In another aspect, an electromagnetic relay is provided. The electromagnetic relay includes a base configured to support relay components. The base includes a perimeter edge. A cover is joined to the base to define an interior volume within the cover. The perimeter edge is received in the cover to define a gap between the cover and the perimeter edge. A soft sealant is provided between the cover and the perimeter edge of the base to fill the gap. The soft sealant forms an air tight seal between the cover and the base.

### BRIEF DESCRIPTION OF THE DRAWINGS

FIG. 1 is a bottom view of a sealed relay assembly formed in accordance with an exemplary embodiment of the present invention.

FIG. 2 is an enlarged fragmentary view of a portion of the relay shown in FIG. 1.

FIG. 3 is an enlarged cross sectional view of the relay base taken along the line 3-3 in FIG. 2.

FIG. 4 is a graph illustrating the relationship between epoxy hardness and sound level from a relay sealed with the epoxy.

FIG. 5 is a perspective view of the relay assembly shown in FIG. 1 with the cover separated from the relay base.

### DETAILED DESCRIPTION OF THE INVENTION

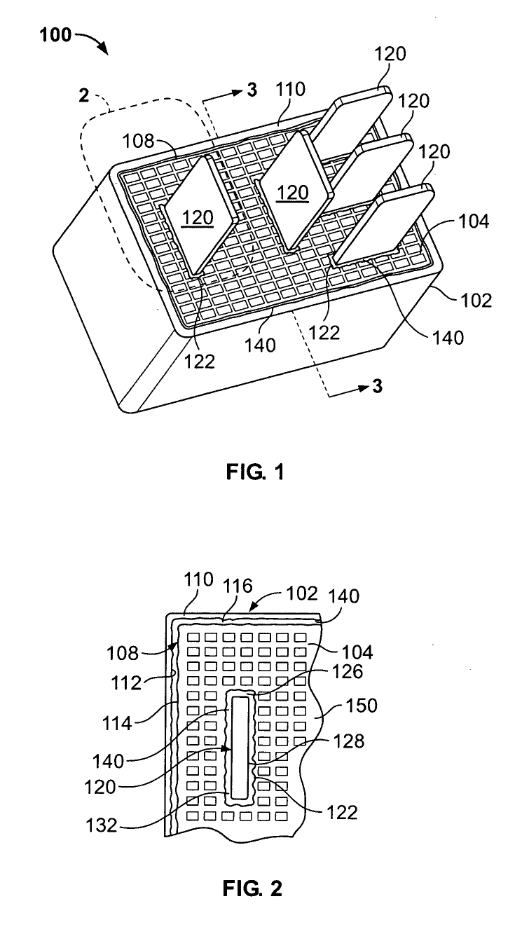

FIG. 1 is a bottom view of a sealed electromagnetic relay assembly 100 formed in accordance with an exemplary embodiment of the present invention. FIG. 2 is an enlarged fragmentary view of a portion of the relay assembly 100 shown in FIG. 1.

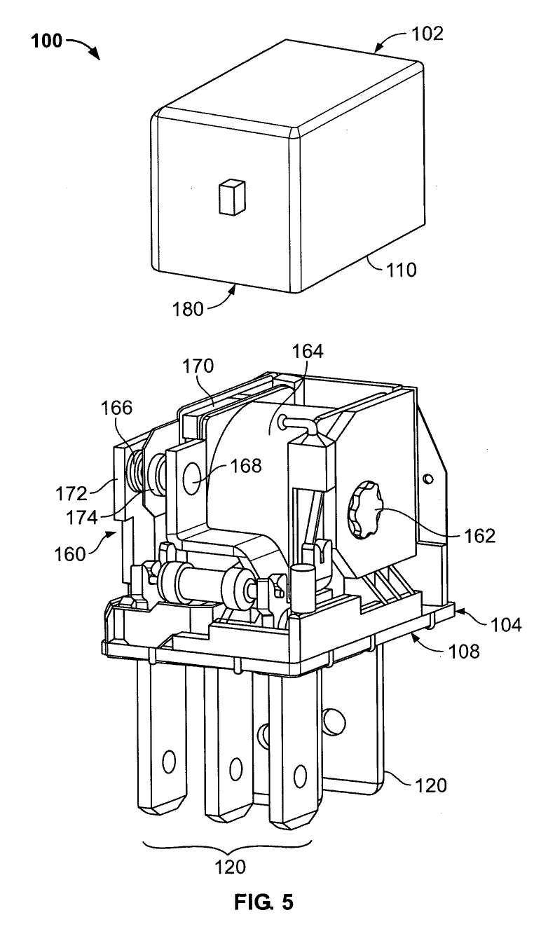

The relay assembly 100 includes a cover 102 and a base 104 that is configured to support relay components (see FIG. 5). The base 104 includes a perimeter edge 108 that is received in the cover 102 to facilitate joining the cover 102 to the base 104. The cover has a lower edge 110 proximate the perimeter edge 108 of the base 104. The lower edge 110 has an inner surface 112. The perimeter edge 108 includes an outer surface 114. The fit between the base 104 and cover 102 is such that a gap 116 is formed between the lower edge inner surface 112 of the cover 102 and the outer surface 114 of the base perimeter edge 108.

Electrical terminals 120 extend through openings 122 formed in the base 204. The terminals 120 are provided for connecting the relay 100 to an electrical circuit or electronic component (not shown). The openings 122 include inner surfaces 126. The terminals 120 have outer surfaces 128. A terminal gap 132 is formed at each terminal 120 between the terminal 120 and the base 104. More specifically, the terminal gap 132 is formed between inner surfaces 126 of the openings 122 and the outer surfaces 128 of the terminals 120.

A soft sealant 140 is applied to fill the gap 116 between the cover 102 and the base 104 and also to fill the terminal gaps 132 between the terminals 120 and the base 104. The soft sealant 140, when cured, forms an air tight seals between the cover 102 and the base 104 and between the terminals 120 and the base 104. The air tight sealing helps to dampen the switching noises within an interior volume 180 (FIG. 5) of the relay assembly 100. As an additional benefit, the life of the relay assembly 100 is extended when operating in an air tight environment. In an exemplary embodiment, the soft sealant 140 is a soft epoxy. The soft sealant has a sufficiently low viscosity before curing to seal a range of gaps. For instance, the gap 116 between the cover 102 and the base 104 typically is in the range of 0.12+/−0.03 millimeters, while terminal gaps 132 of up to 0.25 millimeters may be encountered. The exemplary soft epoxy has a mixed viscosity, before curing, of from about four hundred to about eight hundred centipoises (cps) at seventy-five degrees Fahrenheit and may be used to seal gaps ranging in size from the gap 116 to the terminal gap 132, as noted above, without leaking into the interior volume 180 of the relay assembly 100.

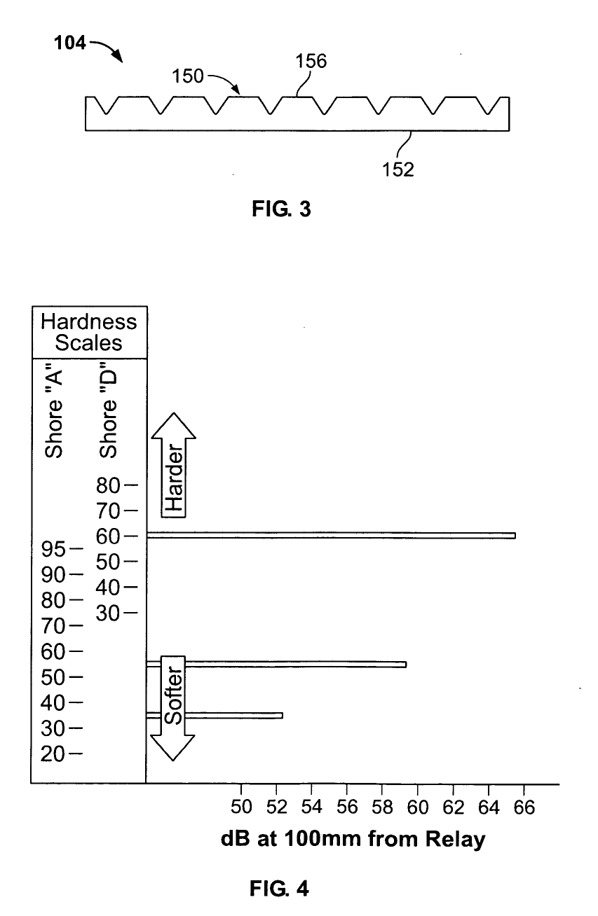

FIG. 3 is a cross sectional view of the relay base 104 taken along the line 3-3 in FIG. 1. The base 104 includes an outer surface 150 and an inner surface 152 upon which the relay components 160 are mounted. In an exemplary embodiment, the outer surface 150 of the base 104 is formed with a V-grid pattern 156 as illustrated in FIG. 3. The soft sealant 140 is dispensed onto the outer surface 150 in a plurality of drops. The V-grid pattern 156 facilitates wetting of the soft sealant 140 to the cover 102, base 104 and terminals 120 which removes entrapped air and improves wicking of the soft sealant 140 into the gap 116 and the terminal gaps 132 between the base 104 and the terminals 120. Alternatively, the soft sealant may be applied directly to the gap 116 and terminal gaps 132. It is to be understood that the benefits of the invention are also applicable to relays not having the V-grid surface 156 on the outer surface 150 of the base 104.

The soft sealant 140 is applied using a heat curing process which facilitates flowing of the soft sealant 140 or wetting between the cover 102 and base 104 and also between the terminals 120 and the base 104. After the heat curing process, the soft sealant 140 is allowed to solidify at room temperature. The soft sealant 140 is sufficiently flexible when cured that stress from shrinkage at the interfaces during and after cooling is reduced so that stress cracking is prevented. Further, the soft sealant 140 has a shore A hardness that facilitates resistance to cracking resulting from thermal cycling. In addition, the soft sealant 140 distributes peeling stress over a wider bond area thereby providing greater resistance to peeling.

FIG. 4 is a graph illustrating the relationship between epoxy hardness and sound level from a relay, such as the relay 100, sealed with the epoxy. Softer epoxies were found to be more effective than harder epoxies at damping the noise of relay operation. For one relay, such as the relay 100, the sound level measured at a distance of one hundred millimeters. At a Shore A hardness of thirty-five, a sound level of fifty-two dB was measured. At a Shore A hardness of 55, a sound level of fifty-nine was measured, while at a Shore D hardness of sixty, a sound level of sixty-five dB was measured. It is to be understood that sound level may vary from one relay to another. It can generally be concluded that softer epoxies are more effective at damping relay noise than harder epoxies. In an exemplary embodiment of the invention, the soft sealant is an epoxy having a Shore A hardness of about forty-five or less. One suitable sealant is a two part epoxy available from Master Bond Incorporated under part number EP37-3FLF40-2.

FIG. 5 is a perspective view of the relay assembly 100 with the cover 102 separated from the base 104 to reveal relay components 160 that are mounted on the base 104. In FIG. 5, the relay assembly is illustrated prior to the application of the soft sealant 140 (FIG. 2). The relay components 160 include a core 162 that is surrounded by a coil 164 and normally open and normally closed stationary contacts 166 and 168, respectively. An armature 170 is attached to a movable spring 172. A movable contact 174 is also attached to the spring 172. The movable contact 174 is moved between engagement positions with the stationary contacts 166 and 168 depending upon the current flow through the coil 164. When the current flow through the coil 164 is sufficient to move the armature 170 toward the core 162, the movable contact 174 is moved to engage the contact 168 thus energizing the relay assembly 100. In the absence of sufficient current in the coil 164 to move the armature 170, the movable contact 174 is in engagement with the contact 166, wherein the relay is de-energized.

The cover 102 and base 104 define an interior volume 180 within the cover 102. A cover 102 cooperates with the base 104 to enclose the relay components 160 within the interior volume 180. The lower edge 110 of the cover 102 is joined to the perimeter edge 108 of the base 104 using the soft sealant 140 as previously described. The electrical terminals 120 extend through the base 104 for connecting the relay assembly 100 to an electrical circuit.

Audible noises are produced when the movable contact 174 engages stationary the contacts 166, 168 and by the impact of the armature 170 with the core 162. The audible noises are communicated through the cover 102 and base 104, and, in some applications, such as in automotive applications, the communicated noises may be objectionable.

The embodiments thus described provide a relay assembly 100 sealed with a soft epoxy 140 that reduces operating noises from the relay. The sealed relay 100 is suitable for use in noise sensitive applications, such as automotive applications, where it is desired to prevent objectionable relay noises from entering the passenger compartment. The soft epoxy 140 is applied using a heat curing process wherein the epoxy wicks around the gap 116 between the relay base 104 and cover 102 and also around the terminal gaps 132 between the base 104 and the terminals 120 extending through the base 104. An air tight seal is formed between the relay base 104 and cover 102. The air tight seal both attenuates noise and prolongs the life of the relay.

While the invention has been described in terms of various specific embodiments, those skilled in the art will recognize that the invention can be practiced with modification within the spirit and scope of the claims.

1. (canceled)

2. The electromagnetic relay of claim 9, wherein said soft sealant is cured to form an airtight seal between said base and said cover.

3. (canceled)

4. The electromagnetic relay of claim 9, further comprising a plurality of electrical terminals extending through said base to form a terminal gap between said terminals and said base, said soft sealant filling said terminal gap.

5-8. (canceled)

9. An electromagnetic relay comprising:
a base configured to support relay components, said base including a perimeter edge, said base having an outer surface with a V-grid pattern formed therein;
a cover joined to said base to define an interior volume within said cover, said perimeter edge being received in said cover to define a gap between said cover and said perimeter edge;
a soft sealant provided between said cover and said perimeter edge of said base to fill said gap, said soft sealant forming an airtight seal between said cover and said base; and
a plurality of electrical terminals extending through said base to form terminal gaps between said terminals and said base, said soft sealant filling said terminal gap, said V-grid pattern facilitating wicking of said soft sealant into said gap and said terminal gaps and facilitating removal of entrapped air.

10. The electromagnetic relay of claim 9, wherein said soft sealant forms a noise dampening seal between said cover and said base to dampen noise produced during relay operation.

11. The electromagnetic relay of claim 9, wherein said perimeter edge is received within said cover and said soft sealant wicks between said perimeter edge and said cover.

12. The electromagnetic relay of claim 9, wherein said soft sealant comprises an epoxy having a Shore A hardness of about forty five or less.

13-14. (canceled)

15. The electromagnetic relay of claim 9, wherein said soft sealant is heat cured.

16. The electromagnetic relay of claim 9, wherein said soft sealant has a mixed viscosity, before curing, from about four hundred to about eight hundred centipoises (cps) at seventy-five degrees Fahrenheit.

17. The electromagnetic relay of claim 9, wherein said soft sealant has a shore A hardness that facilitates resistance to cracking due to thermal cycling.

18-21. (canceled)
